(19) United States
(12) Patent Application Publication
(10) Pub. No.: US 2023/0299006 A1
(43) Pub. Date: Sep. 21, 2023

(54) MEMORY DEVICE AND MANUFACTURING METHOD OF THE MEMORY DEVICE

(71) Applicant: SK hynix Inc., Icheon-si Gyeonggi-do (KR)

(72) Inventors: Chul Young KIM, Icheon-si Gyeonggi-do (KR); Jin Ho BIN, Icheon-si Gyeonggi-do (KR); Ji Yeon BAEK, Icheon-si Gyeonggi-do (KR); Sul Gi JUNG, Icheon-si Gyeonggi-do (KR)

(73) Assignee: SK hynix Inc., Icheon-si Gyeonggi-do (KR)

(21) Appl. No.: 17/884,289

(22) Filed: Aug. 9, 2022

(30) Foreign Application Priority Data
Mar. 17, 2022 (KR) 10-2022-0033620

(51) Int. Cl. H01L 23/535; H01L 27/11582

(52) U.S. Cl. CPC H01L 23/535; H01L 27/11582

(57) ABSTRACT

There are provided a memory device and a manufacturing method of the memory device. The memory device includes: a source line; a stack structure formed on the source line; a cell plug penetrating the stack structure and contacting the source line; a slit separating the stack structure; a source contact formed in the slit, the source contact in contact with the source line; and a compensation plug formed below the cell plug in the source line, wherein the compensation plug contains an impurity that has a higher concentration than an impurity that is contained in the source line.

### CROSS-REFERENCE TO RELATED APPLICATION

The present application claims priority under 35 U.S.C. § 119(a) to Korean patent application number 10-2022-0033620 filed on Mar. 17, 2022, in the Korean Intellectual Property Office, the entire disclosure of which is incorporated by reference herein.

### BACKGROUND

### 1. Technical Field

The present disclosure generally relates to a memory device and a manufacturing method of the memory device, and more particularly, to a memory device having a three-dimensional structure and a manufacturing method of the memory device.

### 2. Related Art

A memory device may be classified into a volatile memory device in which stored data disappears when the supply of power is interrupted and a nonvolatile memory device in which stored data is retained even when the supply of power is interrupted.

The nonvolatile memory device may include a NAND flash memory, a NOR flash memory, a resistive random access memory (ReRAM), a phase-change random access memory (PRAM), a magnetoresistive random access memory (MRAM), a ferroelectric random access memory (FRAM), a spin transfer torque random access memory (STT-RAM), and the like.

Among these, memory cells included in the NAND flash memory may be included in a string connected between a bit line and a source line. The string may include first select transistors, memory cells, and second select transistors, which are connected between the bit line and the source line. Gates of the first select transistors may be connected first select lines, gates of the memory cells may be connected to word lines, and gates of the second select transistors may be connected to second select lines.

### SUMMARY

In accordance with an aspect of the present disclosure, there is provided a memory device including: a source line; a stack structure formed on the source line; a cell plug penetrating the stack structure and contacting the source line; a slit separating the stack structure; a source contact formed in the slit, the source contact in contact with the source line; and a compensation plug formed below the cell plug in the source line, wherein the compensation plug contains an impurity that has a higher concentration than an impurity that is contained in the source line.

In accordance with another aspect of the present disclosure, there is provided a method of manufacturing a memory device, the method including: stacking a first source layer, a first sacrificial layer, and a second source layer on a lower structure; forming a landing hole that exposes a portion of the first source layer by etching portions of the second source layer, the first sacrificial layer, and the first source layer; forming a compensation plug on the bottom of the landing hole, wherein the compensation plug contains an impurity that has a higher concentration than an impurity that is contained in the first and second source layers; filling the landing hole in which the compensation plug is formed with a second sacrificial layer; forming third sacrificial layers and interlayer insulating layers, which are alternately stacked, on the entire structure including the second sacrificial layer; forming a plug hole that exposes the second sacrificial layer by etching portions of the third sacrificial layers and the interlayer insulating layers; exposing the compensation plug by removing the second sacrificial layer that is exposed through the plug hole; and forming a cell plug on the top of the compensation plug that is exposed through the plug hole and the landing hole.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a diagram illustrating a memory device in accordance with an embodiment of the present disclosure.

FIG. 2 is a diagram illustrating a memory cell array.

FIG. 3 is a circuit diagram illustrating a memory block in accordance with an embodiment of the present disclosure.

FIG. 4 is a plan view illustrating a structure of a memory device in accordance with an embodiment of the present disclosure.

FIG. 5 is a sectional view illustrating a structure of a memory device in accordance with an embodiment of the present disclosure.

FIGS. 6A to 6P are views illustrating a manufacturing method of the memory device in accordance with an embodiment of the present disclosure.

FIG. 7 is a diagram illustrating a memory card system to which the memory device of the present disclosure is applied.

FIG. 8 is a diagram illustrating a Solid State Drive (SSD) system to which the memory device of the present disclosure is applied.

### DETAILED DESCRIPTION

The specific structural or functional description disclosed herein is merely illustrative for the purpose of describing embodiments according to the concept of the present disclosure. The embodiments according to the concept of the present disclosure can be implemented in various forms and cannot be construed as limited to the embodiments set forth herein.

Embodiments provide a memory device and a manufacturing method of the memory device, which can reduce a resistance between a source line and a cell plug.

Embodiments also provide a memory device and a manufacturing method of the memory device, which can prevent a physical defect of a source line exposed through a landing hole in an etching process for forming the landing hole.

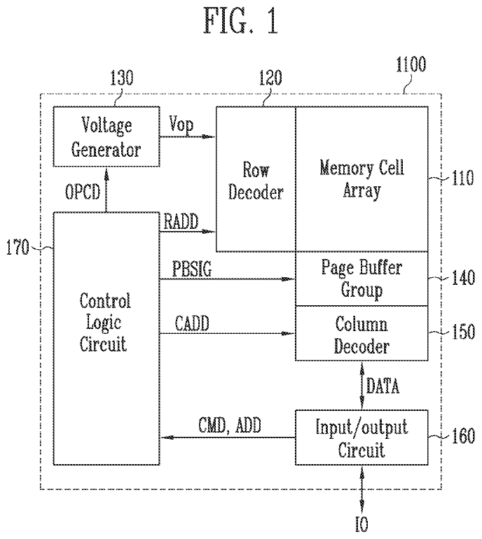

FIG. 1 is a diagram illustrating a memory device in accordance with an embodiment of the present disclosure.

Referring to FIG. 1, the memory device 1100 may include a memory cell array 110 in which data is stored and peripheral circuits 120 to 170 capable of performing a program, read or erase operation.

The memory cell array 110 may include a plurality of memory blocks in which data is stored. Each of the memory blocks may include memory cells, and the memory cells may be implemented in a three-dimensional structure in which the memory cells are stacked in a vertical direction above a substrate.

The peripheral circuits 120 to 170 may include a row decoder 120, a voltage generator 130, a page buffer group 140, a column decoder 150, an input/output circuit 160, and a control logic circuit 170.

The row decoder 120 may select one memory block, among the memory blocks that are included in the memory cell array 110, according to a row address RADD and may transmit operating voltages Vop to the selected memory block.

The voltage generator 130 may generate and output the operating voltages Vop that is necessary for various operations in response to an operation code OPCD. For example, the voltage generator 130 may generate a program voltage, a read voltage, an erase voltage, a pass voltage, a turn-on voltage, a ground voltage, and the like in response to the operation code OPCD and may selectively output the generated voltages.

The page buffer group 140 may be connected to the memory cell array 110 through bit lines. For example, the page buffer group 140 may include page buffers that are connected to the respective bit lines. The page buffers may simultaneously operate in response to page buffer control signals PBSIG and may temporarily store data in a program, read or verify operation. The page buffers may sense a current of the bit lines, which varies according to threshold voltages of the memory cells in a read or verify operation.

The column decoder 150 may transmit data DATA between the input/output circuit 160 and the page buffer group 140 according to a column address CADD.

The input/output circuit 160 may be connected to an external device through input/output lines IO. For example, the external device may be a controller capable of transmitting a command CMD, an address ADD, or data DATA to the resistive memory device 1100. The input/output circuit 160 may input/output a command CMD, an address ADD, and data DATA through the input/output lines IO. For example, the input/output circuit 160 may transmit the command CMD and the address ADD, which are received from the external device, to the control logic circuit 170 through the input/output lines IO and may transmit the data DATA that is received from the external device to the column decoder 150 through the input/output lines IO. The input/output circuit 160 may output the data DATA that is received from the column decoder 150 to the external device through the input/output lines IO.

The control logic circuit 170 that is output the operation code OPCD, the row address RADD, the page buffer control signals PBSIG, and the column address CADD in response to the command CMD and the address ADD. For example, the control logic circuit 170 may include software for performing an algorithm in response to the command CMD and hardware for outputting the address ADD and various control signals.

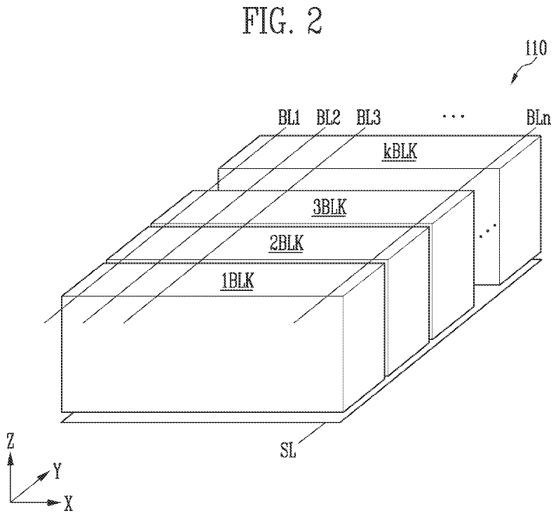

FIG. 2 is a diagram illustrating a memory cell array.

Referring to FIG. 2, the memory cell array 110 may include first to kth memory blocks 1BLK to kBLK (k is a positive integer). Each of the first to kth memory blocks 1BLK to kBLK may include a plurality of memory cells that are stacked in a vertical direction from a substrate. The first to kth memory blocks 1BLK to kBLK may be disposed between a source line SL and first to nth bit lines BL1 to BLn. For example, when the first to nth bit lines BL1 to BLn are disposed to be spaced apart from each other in a first direction (X direction) and are formed to extend in a second direction (Y direction), perpendicular to the first direction (X direction), the first to kth memory blocks 1BLK to kBLK may be disposed to be spaced apart from each other along the second direction (Y direction). Therefore, the memory cells that are included in the first to kth memory blocks 1BLK to kBLK may be stacked along a third direction (Z direction), perpendicular to the first and second directions (X and Y directions).

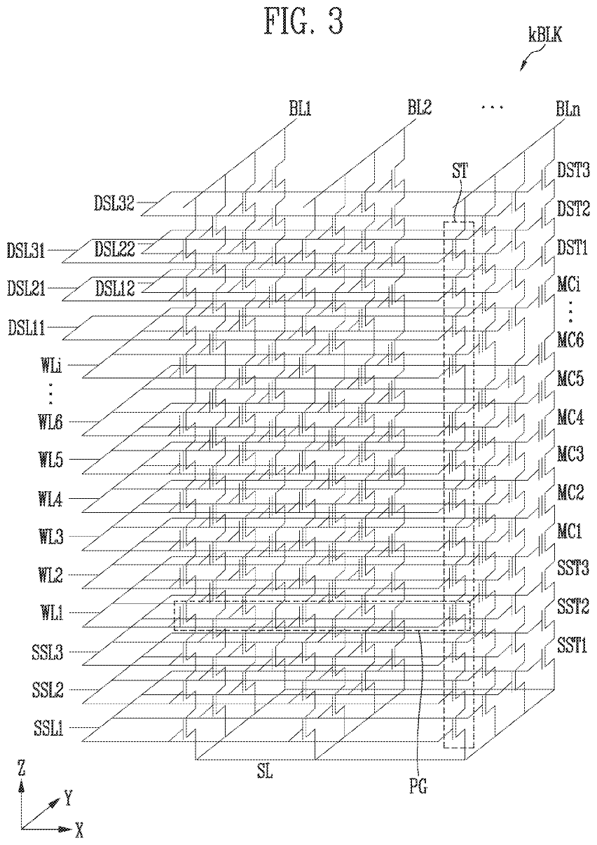

FIG. 3 is a circuit diagram illustrating a memory block in accordance with an embodiment of the present disclosure.

Referring to FIG. 3, the first to kth memory blocks (1BLK to kBLK, which are shown in FIG. 2) may be configured identically to one another, and therefore, the kth memory block kBLK is illustrated as an example.

The kth memory block kBLK may include strings ST that are connected between the first to nth bit lines BL1 to BLn and the source line SL. Since the first to nth bit lines BL1 to BLn extend along the second direction (Y direction) and are arranged to be spaced apart from each other along the first direction (X direction), the strings ST may also be arranged to be spaced apart from each other along the first and second directions (X and Y directions). For example, strings ST may be connected between the first bit line BL1 and the source line SL, and strings ST may be arranged between the second bit line BL2 and the source line SL. In this manner, strings ST may be arranged between the nth bit line BLn and the source line SL. The strings ST may extend along the third direction (Z direction).

Any one string ST, among the strings ST that are connected to the nth bit line BLn, will be described as an example. The string ST may include first to third source select transistors SST1 to SST3, first to ith memory cells MC1 to MCi, and first to third drain select transistors DST1 to DST3. The kth memory block kBLK, shown in FIG. 3, is a drawing for understanding the structure of a memory block, and therefore, the numbers of source select transistors, memory cells, and drain select transistors, which are included in the strings ST, may be changed according to a memory device.

Gates of first to third source select transistors SST1 to SST3 that are included in different strings may be connected to first to third source select lines SSL1 to SSL3, gates of first to ith memory cells MC1 to MCi, which are included in different strings, may be connected to first to ith word lines WL1 to WLi, and gates of first to third drain select transistors DST1 to DST3, which are included in different strings, may be connected to eleventh, twelfth, twenty-first, twenty-second, thirty-first, and thirty-second drain select lines DSL11, DSL12, DSL21, DSL22, DSL31, and DSL32.

For example, the first source select line SSL may be commonly connected to first source transistors SST1 that are arranged at the same distance from the substrate. In other words, first source select transistors SST1 that are formed in the same layer may be commonly connected to the first source select line SSL1. In this manner, second source select transistors SST2 that are formed in a layer different from the layer in which the first source select transistors SST1 are formed may be commonly connected to the second source select line SSL2, and third source select transistors SST3 that are formed in a layer different from the layer in which the second source select transistors SST2 are formed may be commonly connected to the third source select line SSL3. The first to third source select lines SSL1 to SSL3 may be respectively formed in different layers.

In the manner described above, ith memory cells MC1 that are formed in the same layer may be commonly connected to the ith word line WLi, and the first to ith word lines WL1 to WLi may be respectively formed in different layers. A group of memory cells that are included in different strings ST and connected to the same word line becomes a page PG.

First to third drain select transistors DST1 to DST3 that are included in different strings ST may be connected to drain select lines that are isolated from each other. Specifically, each of first to third drain select transistors DST1 to DST3 that are arranged along the first direction (X direction) may be connected to the same drain select line, and first to third drain select transistors DST1 to DST3 that are arranged along the second direction (Y direction) may be connected to drain select lines that are isolated from each other. For example, some of the first drain select transistors DST may be connected to the eleventh drain select line DSL11, and the other of the first drain select transistors DST may be connected to the twelfth drain select line DSL12. The twelfth drain select line DSL12 may be a line that is isolated from the eleventh drain select line DSL11. Therefore, a voltage that is applied to the eleventh drain select line DSL11 may be different from a voltage that is applied to the twelfth drain select line DSL12. In this manner, some of the second drain select transistors DST2 may be connected to the twenty-first drain select transistor DSL21, and the other of the second drain select transistors DST2 may be connected to the twenty-second drain select line DSL22. Some of the third drain select transistors DST3 may be connected to a thirty-first drain select line DSL31, and the other of the third drain select transistors DST3 may be connected to the thirty-second drain select line DSL 32.

Although not shown in FIG. 3, dummy lines may be disposed between a drain select line and a word line, and dummy lines may also be disposed between a source select line and a word line.

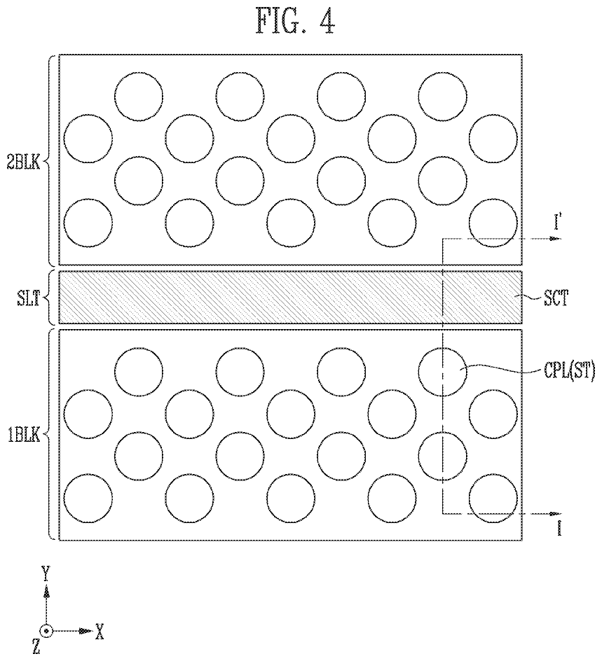

FIG. 4 is a plan view illustrating a structure of a memory device in accordance with an embodiment of the present disclosure.

Referring to FIG. 4, first and second memory blocks 1BLK and 2BLK may be formed on a plane in first direction X and second direction Y. The first and second memory blocks 1BLK and 2BLK may be distinguished from each other by a slit SLT. When the slit SLT extends in the first direction X, the first and second memory blocks 1BLK and 2BLK may be disposed to be distinguished from each other along the second direction Y. In an embodiment, FIG. 4 shows a region in which the first and second memory blocks 1BLK and 2BLK, among the first to kth memory blocks 1BLK to kBLK that are included in the memory cell array 110, shown in FIG. 2, are formed, and therefore, the other second to kth memory blocks 2BLK to kBLK may also be distinguished from each other by the slit SLT. The region in which the first and second memory blocks 1BLK and 2BLK are formed in a region in which the first to kth memory blocks 1BLK to kBLK are formed will be exemplarily described as follows.

A plurality of cell plugs CPL may be included in the first and second memory blocks 1BLK and 2BLK. In FIG. 3, each of the cell plugs CPL may correspond to the string ST. For example, the cell plugs CPL may be arranged to be spaced apart from each other along the first direction X or the second direction Y and may extend along a third direction Z vertical to a substrate. Since gate lines of memory cells, among a plurality of memory cells that are included in the same memory block, formed on the same plane, are connected to each other, gate lines of different memory blocks that are formed on the same plane may be separated from each other by the slit SLT.

The slit SLT may be filled with an insulating material, but a source contact SCT may be formed in the slit SLT to decrease the size of the memory device. The source contact SCT may transfer a source voltage, supplied through a line, formed above the first and second memory blocks 1BLK and 2BLK to a source line that is formed under the first and second memory blocks 1BLK and 2BLK. The source line may be commonly connected to a plurality of memory blocks, and hence, an electrical characteristic change of the source line may have influence on the plurality of memory blocks. In this embodiment, a compensation plug that contains a high concentration impurity may be formed on the bottom of the cell plug to prevent a physical defect of the source line that is exposed through a landing hole in an etching process for forming the landing hole and to reduce the resistance of a region in which the source contact SCT and the source line are in contact with each other. A memory device including a compensation plug and a manufacturing method of the memory device will be described in detail as follows.

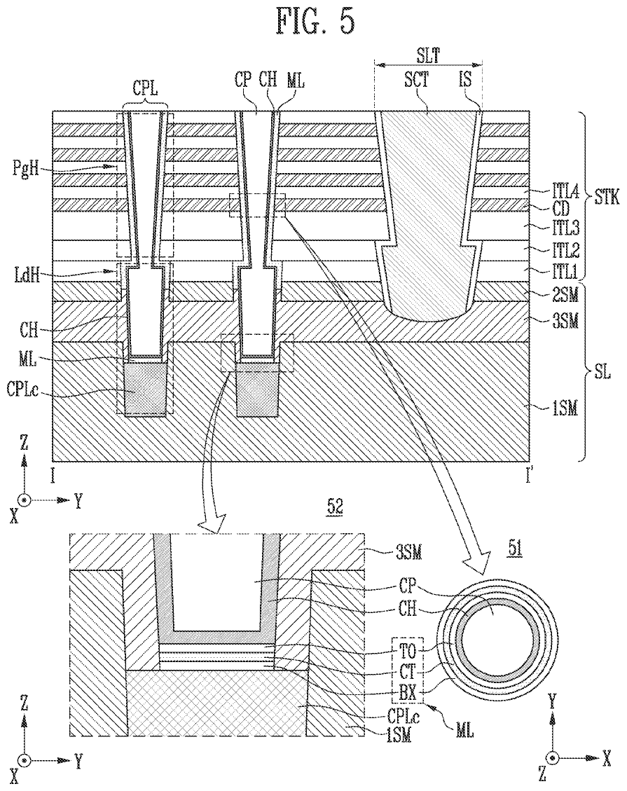

FIG. 5 is a sectional view illustrating a structure of a memory device in accordance with an embodiment of the present disclosure.

Referring to FIG. 5, the memory device may include a source line SL, a stack structure STK, cell plugs CPL, compensation layers CPLc, and a source contact SCT, which are formed on a lower structure (not shown). A plurality of cell plugs CPL and a plurality of compensation plugs CPLc may be included in the memory device. However, in the following embodiment, any one of the plurality of cell plugs CPL and any one of the plurality of compensation plugs CPLc are described as an example. Although not shown in the drawing, the lower structure may be a substrate or a peripheral circuit structure.

The source line SL may include first source layer 1SM, a third source layer 3SM, and a second source layer 2SM, which are stacked. For example, the third source layer 3SM may be formed on the top of the first source layer 1SM, and the second source layer 2SM may be formed on the top of the third source layer 3SM. The first, third, and second source layers 1SM, 3SM, and 2SM may be formed of a conductive material. For example, the first, third, and second source layers 1SM, 3SM, and 2SM may be formed of a conductive material, such as poly-silicon, tungsten, or nickel. In addition, various kinds of conductive materials may be used.

The stack structure STK may include first to third interlayer insulating layers ITL1 to ITL3 stacked on the source line SL, and conductive layers CD and fourth interlayer insulating layers ITL4, which are alternately stacked. The first to fourth interlayer insulating layers ITL1 to ITL4 may be formed with an oxide layer or a silicon oxide layer. The conductive layers CD may be formed of a conductive material used for gate lines. For example, the conductive layers CD may be formed of a metal material such as tungsten (W), molybdenum (Mo), cobalt (Co) or nickel (Ni), or a semiconductor material such as silicon (Si) or poly-silicon (Poly-Si), but the present disclosure is not limited thereto.

The cell plug CPL may protrude even to a portion of the source line SL while penetrating the stack structure STK. For example, the cell plug CPL may penetrate the stack structure STK along the third direction Z, and a lower portion of the cell plug CPL may protrude into the source line SL. The cell plug CPL may be formed inside a portion of a landing hole LdH that is formed in the source line SL and a plug hole PgH that is formed in the stack structure STK. A partial upper region of the landing hole LdH may overlap with a partial lower region of the stack structure STK. The cell plug CPL may include a memory layer ML, a channel layer CH, and a core pillar CP, which are formed inside the portion of the landing hole LdH and the plug hole PgH. For example, the memory layer ML may be formed in a cylindrical shape along partial inner wall of the landing hole LdH and an inner wall of the plug hole PgH, and the channel layer CH may be formed in a cylindrical shape along an inner wall of the memory layer ML. The core pillar CP may be formed in a cylindrical shape along an inner wall of the channel layer CH.

A portion 51 of the memory layer ML, which is formed in the same layer as each of the conductive layers CD, may become a memory cell. The memory cell with a planar structure in an X-Y direction will be described as follows. The memory cell may include a core pillar CP having a cylindrical shape and may include a channel layer CH that surrounds a side surface of the core pillar CP, a tunnel insulating layer TO that surrounds a side surface of the channel layer CH, a charge trap layer CT that surrounds a side surface of the tunnel insulating layer TO, and a blocking layer BX that surrounds a side surface of the charge trap layer CT. The tunnel insulating layer TO, the charge trap layer CT, and the blocking layer BX, which surround the channel layer CH, may be included in the memory layer ML.

The channel layer CH that is included in the cell plug CPL may extend in the third direction Z in the plug hole PgH and the landing hole LdH, but a portion of the memory layer ML may be removed in the landing hole LdH. The channel layer CH may be in contact with the source line SL in a region in which the portion of the memory layer ML is removed.

The compensation plug CPLc may be formed on the bottom of the cell plug CPL in the landing hole LdH. The compensation plug CPLc may be formed in the first source layer 1SM that is included in the source line SL, but a height of an uppermost end of the compensation plug CPLc may be set at a position that is lower than a height of an uppermost end of the third source layer 3SM.

Referring to an enlarged view (52) of a partial region in which the compensation plug CPLc is formed, the compensation plug CPLc may is be formed in the landing hole LdH and may be formed on the bottom of the cell plug CPL in the landing hole LdH.

The compensation plug CPLc may reduce a resistance between the cell plug CPL and the source line SL and may be formed of a material that contains an impurity that has a higher concentration than the impurity that is contained in the first or second source layer 1SM or 2SM. For example, in a manufacturing process of the memory device, i.e., an etching or cleaning process for forming the landing hole LdH in the first and second source layers 1SM and 2SM, surfaces of the first and second source layers 1SM and 2SM, which are exposed through the landing hole LdH, may be physically damaged. This physical damage may increase as a concentration of an impurity that is contained in the first and second source layers 1SM and 2SM becomes higher. When the concentration of the impurity that is contained in the first and second source layers 1SM and 2SM is lowered so as to reduce the physical damage of the first and second source layers 1SM and 2SM in the manufacturing process, an electrical characteristic of the source line SL may be deteriorated. Therefore, in this embodiment, the compensation plug CPLc, made of a material that includes an impurity that has a higher concentration than a reference concentration, may be formed on the bottom of the cell plug CPL so as to prevent physical damage of the source line SL, preventing the deterioration of the electrical characteristic of the source line SL.

The impurity that is contained in the compensation plug CPLc is may be the same ion as the impurity that is contained in the first to third source layers 1SM to 3SM or may be an ion capable of reducing a resistance of the source line SL. For example, the impurity that is contained in the compensation plug CPLc may be a phosphorous or boron ion. In addition, materials that contain various ions capable of improving an electrical characteristic of the source line SL may be used for the compensation plug CPLc.

The source contact SCT may protrude into and past the source line SL, thereby penetrating a portion of the stack structure STK. For example, the source contact SCT may penetrate the stack structure STK along the third direction Z, and a lower portion of the source contact SCT may protrude into the source line SL. The source contact SCT may be formed in a slit SLT to separate the conductive layers CD that are included in the stack structure STK from each other. For example, the slit SLT may be a trench that separates the conductive layers CD from each other in the first direction X and the fourth interlayer insulating layers ITL4 from each other in the first direction X. The slit SLT may be formed to expose a portion of the source line SL. The conductive layers CD may be exposed through a side surface of the slit SLT, and hence, an insulating layer IS may be formed on the side surface of the slit SLT. Therefore, the source contact SCT that is made of a conductive material may be formed inside the slit SLT in which the insulating layer IS is formed. The source contact SCT might not be in contact with the conductive layers CD of the stack structure STK but may be in contact with the source line SL. The source contact SCT may be formed of a conductive material. For example, the source contact SCT may be formed of a conductive material, such as poly-silicon or tungsten.

A manufacturing method of the above-described memory device will be described in detail as follows.

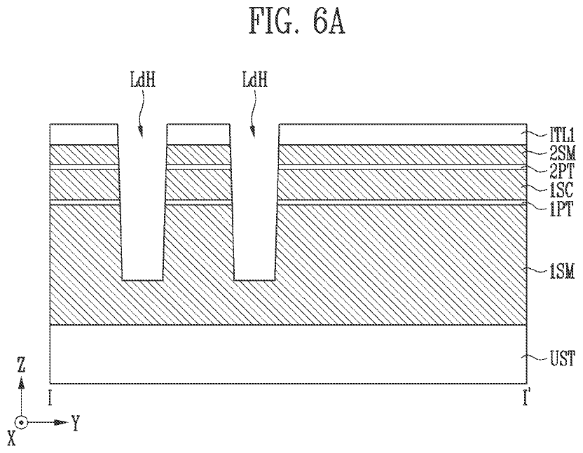

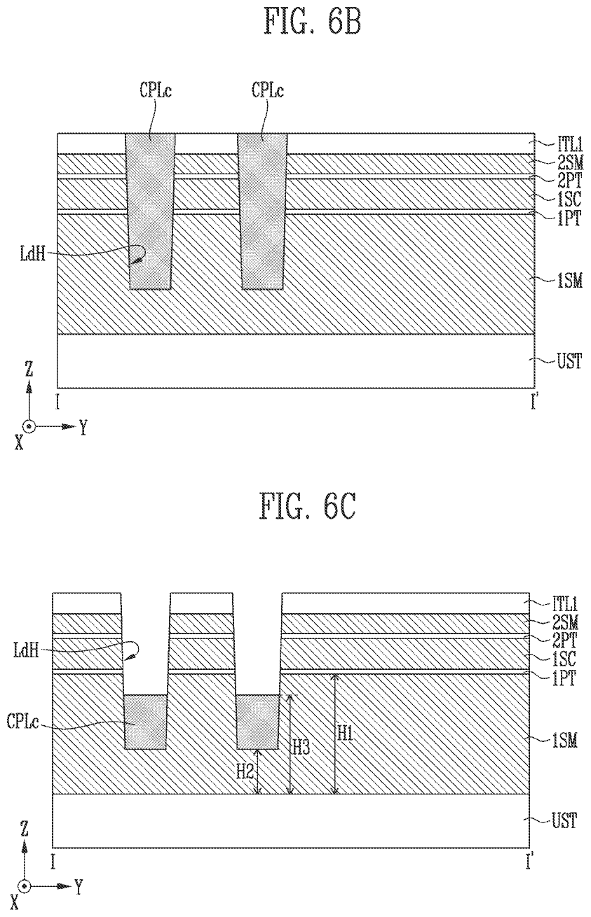

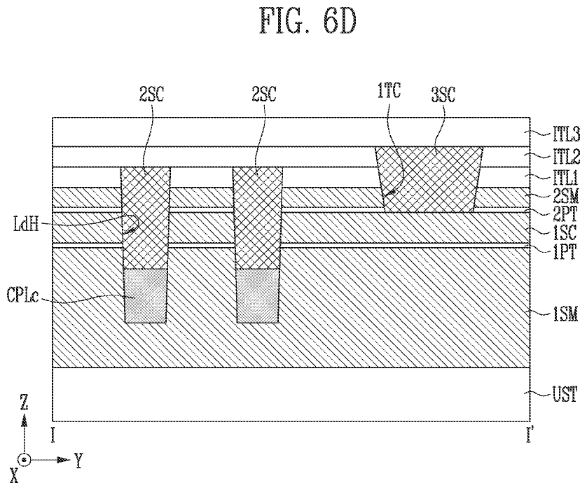

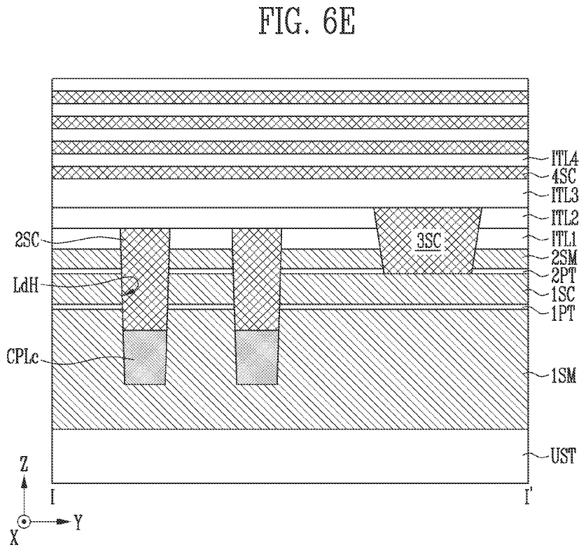

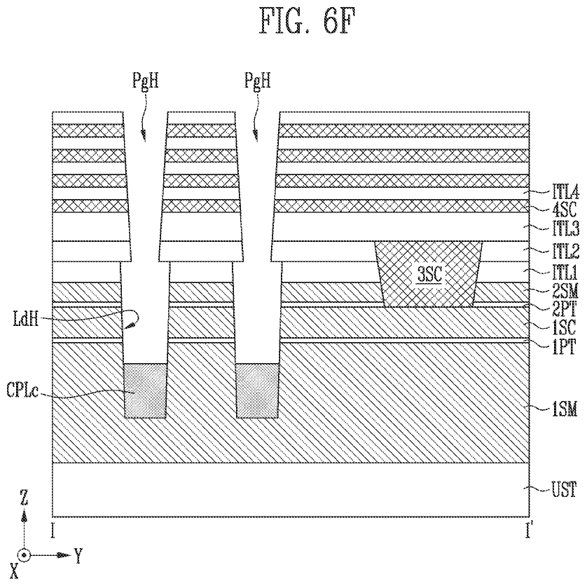

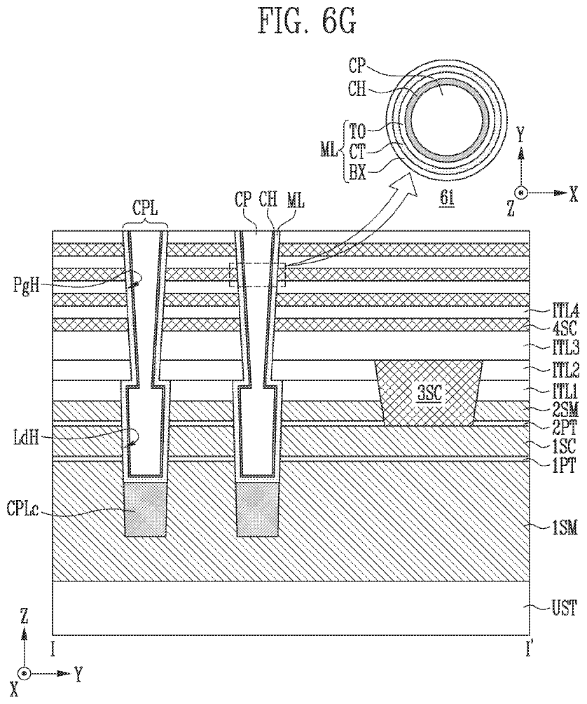

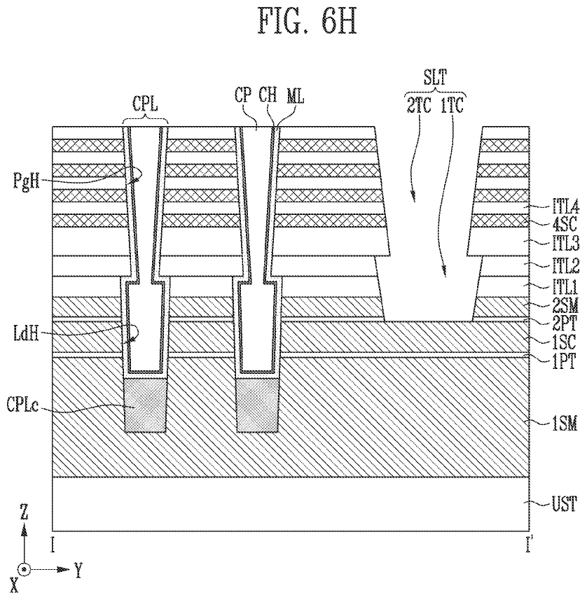

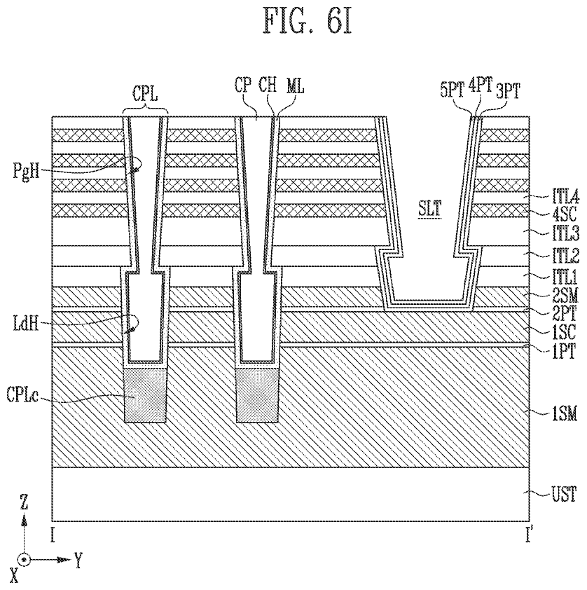

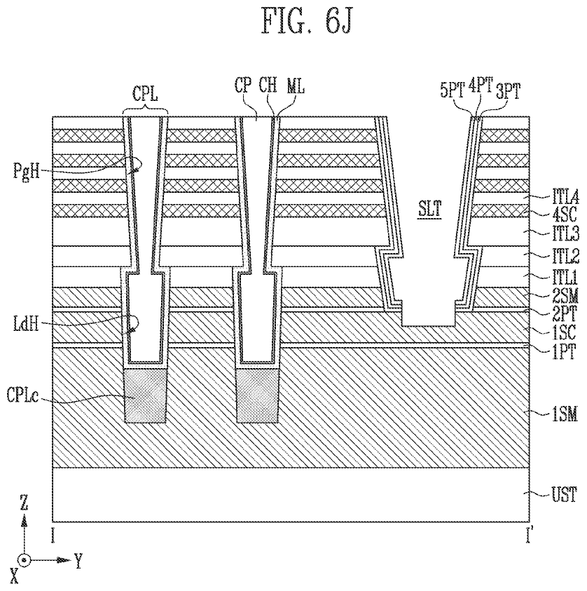

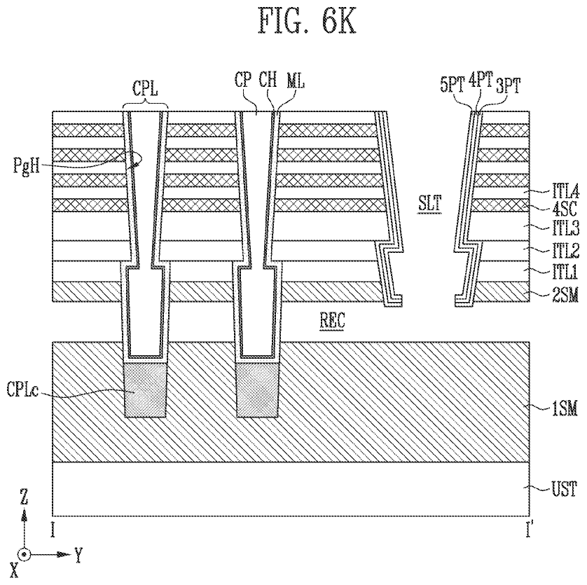

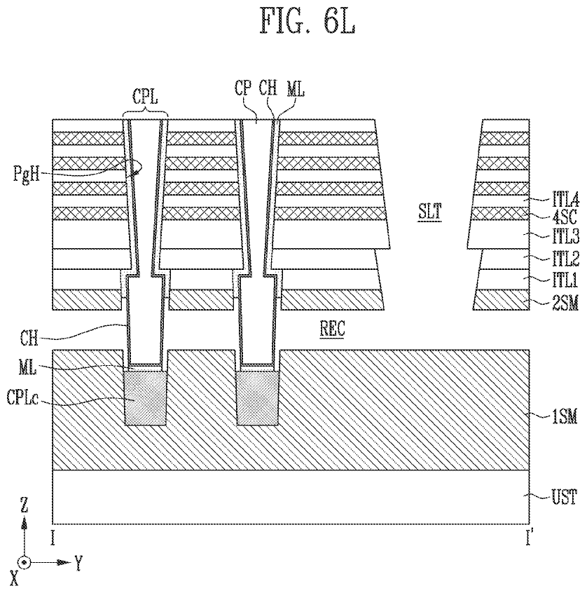

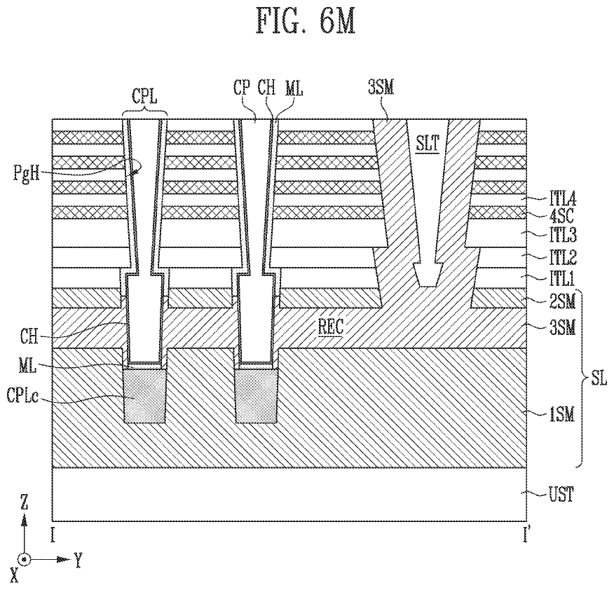

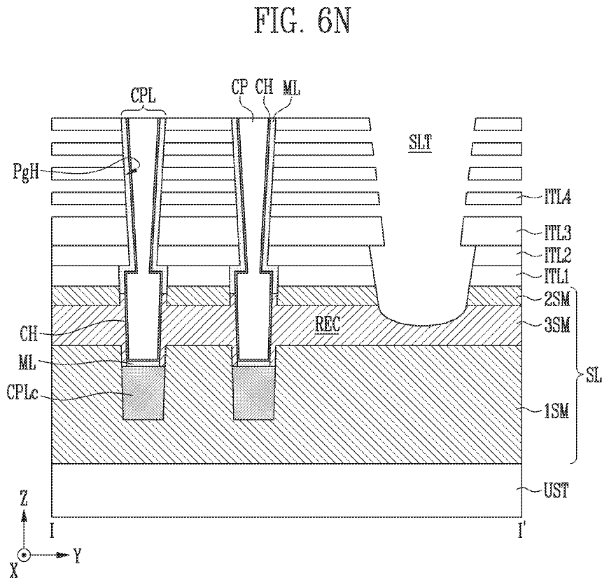

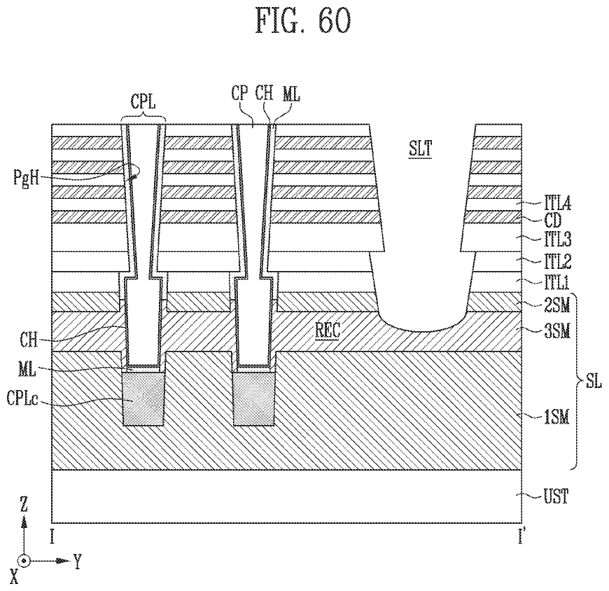

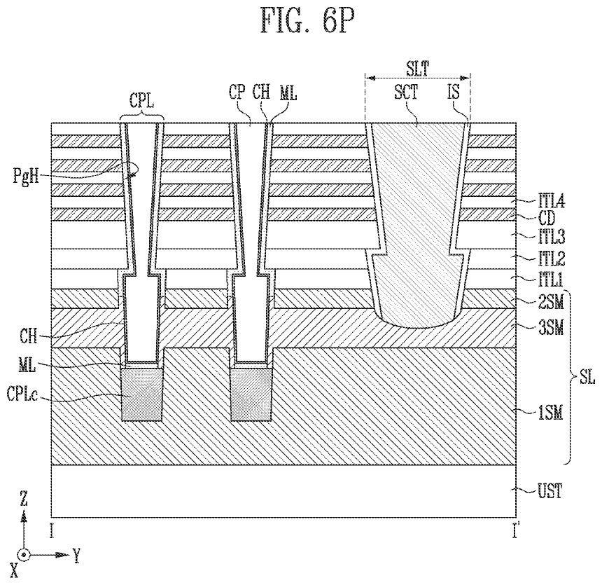

FIGS. 6A to 6P are views illustrating a manufacturing method of the memory device in accordance with an embodiment of the present disclosure.

Referring to FIG. 6A, a first source layer 1SM, a first protective layer 1PT, a first sacrificial layer 1SC, a second protective layer 2PT, a second source layer 2SM, and a first interlayer insulating layer ITL1 may be stacked on the top of a lower structure UST. The lower structure UST may be a substrate or a peripheral circuit structure. The peripheral circuit structure may include transistors and lines, which are configured to perform a program, read, or erase operation. The first source layer 1SM may be a conductive layer to be used for a source line and may be formed of poly-silicon containing an impurity. The first protective layer 1PT may be formed on the top of the first source layer 1SM and may be used as a layer for protecting a surface of the first source layer 1SM in a subsequent etching process. The first protective layer 1PT may be formed of a material having an etch selectivity that is different from an etch selectivity of the first source layer 1SM. For example, the first protective layer 1PT may be formed as an oxide layer or a silicon oxide layer. The first sacrificial layer 1SC may be formed of a material that is removed in a subsequent process and may be formed on the top of the first protective layer 1PT. The first sacrificial layer 1SC may be formed of a material having an etch selectivity that is different from the etch selectivity of the first protective layer 1PT. For example, the first sacrificial layer 1SC may be formed of the same material as the first source layer 1SM. The second protective layer 2PT may be a layer for protecting the second source layer 2SM in a process of removing the first sacrificial layer 1SC and may be formed on the top of the first sacrificial layer 1SC. For example, the second protective layer 2PT may be formed of a material having an etch selectivity that is different from an etch selectivity of the second source layer 2SM. For example, the second protective layer 2PT may be formed of the same material as the first protective layer 1PT. The second source layer 2SM may be a conductive layer to be used for the source line and may be formed of poly-silicon containing the impurity. The first interlayer insulating layer ITL1 may be formed as an oxide layer or a silicon oxide layer. For example, the first source layer 1SM, the first sacrificial layer 1SC, and the second source layer 2SM may be formed of a material having a lower impurity concentration than a reference concentration at which physical defects of the first and second source layers 1SM and 2SM do not occur or can be minimized when exposed in an etching process.

After the first source layer 1SM, the first protective layer 1PT, the first sacrificial layer 1SC, the second protective layer 2PT, the second source layer 2SM, and the first interlayer insulating layer ITL1 are stacked on the top of the lower structure UST, a landing hole LdH may be formed, which penetrates the first interlayer insulating layer ITL1, the second source layer 2SM, the second protective layer 2PT, the first sacrificial layer 1SC, the first protective layer 1PT, and the first source layer 1SM. For example, the landing hole LdH may penetrate the first interlayer insulating layer ITL1, the second source layer 2SM, the second protective layer 2PT, the first sacrificial layer 1SC, and the first protective layer 1PT in a vertical direction and may be formed such that a lowermost end of the landing hole LdH is located in the first source layer 1SM. That is, an etching process for forming the landing hole LdH may be stopped before the lower structure UST is exposed.

Referring to FIG. 6B, a compensation plug CPLc may be formed inside the landing hole LdH. The compensation plug CPLc may be formed of a conductive material. For example, the conductive material for the compensation plug CPLc may include an impurity that has a higher concentration than the impurity of the first or second source layer 1SM or 2SM. For example, the compensation plug CPLc may be formed of poly-silicon. The impurity contained in the compensation plug CPLc may be a phosphorous or boron ion, but various ions capable of improving an electrical characteristic of the source line may be used in addition to the phosphorous or boron ion.

Referring to FIG. 6C, the height of the compensation plug CPLc may be lowered by etching a portion of the compensation plug CPLc. The etching process for lowering the height of the compensate plug CPLc may be performed until an uppermost end of the compensation plug CPLc becomes lower than an uppermost end of the first source layer 1SM. For example, it is assumed that the height from the lowermost end to the uppermost end of the first source layer 1SM is a first height H1, the height from the lowermost end of the first source layer 1SM to the lowermost end of the landing hole LdH is a second height H2, and the height from the lowermost end of the first source layer 1SM to the uppermost end of the compensation plug CPLc is a third height H3. The third height H3 may be set to be lower than the first height H1 and to be higher than the second height H2.

Referring to FIG. 6D, a second sacrificial layer 2SC may be formed on the top of the compensation plug CPLc in the landing hole LdH. The second sacrificial layer 2SC may be formed of any one material among titanium nitride (TiN), tungsten (W), and carbon (C) or may be formed of a mixture thereof. When the second sacrificial layer 2SC is formed of a mixture of titanium nitride (TiN), tungsten (W), and carbon (C), a plurality of layers made of different materials may be alternately stacked. For example, when the second sacrificial layer 2SC is formed of titanium nitride (TiN) and tungsten (W), a plurality of stacked layers including titanium nitride (TiN) and tungsten (W) may be formed as the second sacrificial layer 2SC on the top of the compensation plug CPLc. Subsequently, a second interlayer insulating layer ITL2 may be formed on the entire structure in which the second sacrificial layer 2SC is formed. Subsequently, a first trench 1TC may be formed by etching portions of the second and first interlayer insulating layers ITL2 and ITL1, the second source layer 2SM, and the second protective layer 2PT, and a third sacrificial layer 3SC may be formed in the first trench 1TC. For example, the first trench 1TC may be formed in the same region as a region in which a slit is to be formed, and the etching process for forming the first trench 1TC may be performed until the first sacrificial layer 1SC is exposed. The third sacrificial layer 3SC may be formed of any one material among titanium nitride (TiN), tungsten (W), and carbon (C) or may be formed of a mixture thereof. When the third sacrificial layer 3SC is formed of a mixture of titanium nitride (TiN), tungsten (W), and carbon (C) are mixed, a plurality of layers made of different materials may be alternately stacked. For example, when the third sacrificial layer 3SC is formed of titanium nitride (TiN) and tungsten (W), a plurality of stacked layers including titanium nitride (TiN) and tungsten (W) may be formed as the third sacrificial layer 3SC on the top of the compensation plug CPLc. After the third sacrificial layer 3SC is formed in the first trench 1TC, a third interlayer insulating layer ITL3 may be formed on the entire structure. The third interlayer insulating layer ITL3 may be formed as an oxide layer or a silicon oxide layer.

Referring to FIG. 6E, a fourth sacrificial layers 4SC and fourth interlayer insulating layers ITL4 may be alternately stacked on the third interlayer insulating layer ITL3. The fourth sacrificial layers 4SC may be formed of a material having an etch selectivity that is different from an etch selectivity of the fourth interlayer insulating layers ITL4. For example, each of the fourth sacrificial layers 4SC may be formed as a nitride layer. Each of the fourth interlayer insulating layers ITL4 may be formed as an oxide layer or a silicon oxide layer.

Referring to FIG. 6F, an etching process may be performed such that a plug hole PgH is formed on the top of the landing hole LdH. For example, the plug hole PgH may be formed by etching portions of the fourth sacrificial layers 4SC and the fourth interlayer insulating layers ITL4 such that the second sacrificial layer (2SC shown in FIG. 6E) is exposed, and an etching process for removing the second sacrificial layer 2SC that is exposed through the plug hole PgH may be performed. Therefore, the plug hole PgH and the landing hole LdH may be connected to each other, and the compensation plug CPLc may be exposed through the plug hole PgH and the landing hole LdH.

Referring to FIG. 6G, a cell plug CPL may be formed on the top of the compensation plug CPLc. Each cell plug CPL may include a memory layer ML, a channel layer CH, and a core pillar CP, which are sequentially formed along surfaces of the plug hole PgH and the landing hole LdH and an upper surface of the compensation plug CPLc. The memory layer ML may be formed in a cylindrical shape along a top surface of the compensation plug CPLc, a side surface of the landing hole LdH, and a side surface of the plug hole PgH, the channel layer CH may be formed in a cylindrical shape along an inner surface of the memory layer ML, and the core pillar CP may be formed in a cylindrical shape that fills an inner region of the channel layer CH.

A portion of the cell plug CPL, which is formed in the same layer as each of the fourth sacrificial layers 4SC, may become a memory cell 61. An X-Y planar structure of the memory cell 61 will be described as follows. The memory cell 61 may include a core pillar CP that is formed in a cylindrical shape and may include a channel layer CH that surrounds the periphery of the core pillar CP, a tunnel insulating layer TO that surrounds the periphery of the channel layer CH, a charge trap layer CT that surrounds the periphery of the tunnel insulating layer TO, and a blocking layer BX that surrounds the periphery of the charge trap layer CT. The tunnel insulating layer TO, the charge trap layer CT, and the blocking layer BX, which surround the channel layer CH, may be included in the memory layer ML. A bottom surface of the blocking layer BX that is included in the cell plug CPL may be in contact with the compensation plug CPLc.

Referring to FIG. 6H, a second trench 2TC may be formed by etching portions of the fourth sacrificial layers 4SC and the fourth interlayer insulating layers ITL4, which are stacked on the top of the third sacrificial layer (3SC shown in FIG. 6G). For example, the etching process that forms the second trench 2TC may be performed until the third sacrificial layer 3SC, filled in the first trench 1TC, is exposed. When the third sacrificial layer 3SC is exposed through the first trench 1TC, an etching process for removing the exposed third sacrificial layer 3SC may be performed. A region in which the third sacrificial layer 3SC is removed may become the first trench 1TC, and therefore, the first and second trenches 1TC and 2TC may be connected to each other. Since the second trench 2TC may be formed in a shape for distinguishing memory blocks from each other, the first and second trenches 1TC and 2TC may become a slit SLT for distinguishing memory blocks from each other.

Referring to FIG. 6I, third to fifth protective layers 3PT to 5PT may be sequentially formed along an inner surface of the slit SLT. The third to fifth protective layers 3PT to 5PT may be used as layers for protecting the fourth sacrificial layers 4SC or the fourth interlayer insulating layers ITL4 through the slit SLT in a subsequent etching process and may be formed in an order of a nitride layer, an oxide layer, and a nitride layer. For example, each of the third and fifth protective layers 3PT and 5PT may be formed as a nitride layer, and the fourth protective layer 4PT may be formed as an oxide layer.

Referring to FIG. 6J, an etching process may be performed such that the first sacrificial layer 1SC is exposed through the bottom of the slit SLT. For example, the etching process may be performed as an anisotropic dry etching process such that the third to fifth protective layers 3PT to 5PT that are formed on a side surface of the slit SLT remain and such that the first sacrificial layer 1SC is exposed.

Referring to FIG. 6K, an etching process for removing the first sacrificial layer (1SC shown in FIG. 6J) that is exposed through the bottom of the slit SLT may be performed. For example, the etching process may be performed as an isotropic dry etching process or a wet etching process. An empty region in which the first sacrificial layer 1SC is removed may be defined as a recess REC. When the first and second protective layers (1PT and 2PT, which are shown in FIG. 6J) remain in the recess REC after the first sacrificial layer 1SC is removed, an etching or cleaning process for removing the first and second protective layers 1PT and 2PT may be additionally performed. Accordingly, the memory layer ML, the first source layer 1SM, and the second source layer 2SM may be exposed through the inside of the recess REC.

Referring to FIG. 6L, etching processes for removing a portion of the memory layer ML through the slit SLT and the recess REC may be performed. Specifically, a portion of the memory layer ML, which is exposed through the recess REC, in the memory layer ML that is included in the cell plug CPL may be removed. Since the memory layer ML is configured with the blocking layer (BX shown in FIG. 6G), the charge trap layer (CT shown in FIG. 6G), and the tunnel insulating layer (TO shown in FIG. 6G), etching processes for sequentially removing the blocking layer BX, the charge trap layer CT, and the tunnel insulating layer TC, which are exposed through the recess REC, may be sequentially performed. The third to fifth protective layers 3PT to 5PT that remain on the side surface of the slit SLT may also be sequentially removed. Therefore, the channel layer CH that is included in the plug PL may be exposed through the inside of the recess REC. When the exposed portion of the memory layer ML is removed through the recess REC, a portion of the memory layer ML, which is formed in a region that overlaps with the first and second source layers 1SM and 2SM, may also be removed.

Referring to FIG. 6M, a third source layer 3SM may be formed inside the recess REC through the slit SLT, so that a source line SL configured with the first to third source layers 1SM to 3SM is formed. For example, since the recess REC is connected to the slit SLT, the third source layer 3SM may be formed along the side surface of the slit SLT when the recess REC is filled with the third source layer 3SM. The third source layer 3SM may be formed of a conductive material. For example, the third source layer 3SM may be formed of the same material as the first or second source layer 1SM or 2SM or may be formed of a material having an impurity that has a high concentration than the impurity of the first or second source layer 1SM or 2SM. For example, the third source layer 3SM may be formed of a conductive material, such as poly-silicon.

Referring to FIG. 6N, an etching process for removing a portion of the third source layer 3SM that is formed in the slit SLT may be performed. For example, since the third source layer 3SM is formed on the side and bottom surfaces of the slit SLT, the etching process for removing the portion of the third source layer 3SM that is formed in the slit SLT may be performed as an isotropic dry etching process or a wet etching process. The etching process may be performed until the third source layer 3SM that is formed on the side surface of the slit SLT is removed, and therefore, a portion of the third source layer 3SM may remain on the bottom of the slit SLT. When the third source layer 3SM that is formed on the side surface of the slit SLT is removed, the fourth sacrificial layers (4SC shown in FIG. 6M) may be exposed through the is side surface of the slit SLT. Subsequently, an etching process for removing the fourth sacrificial layers 4SC that are exposed through the slit SLT may be performed. The etching process may be performed by using a source gas or an etchant, which has a high etch selectivity with respect to the fourth sacrificial layers 4SC as compared with the fourth interlayer insulating layers ITL4 such that the fourth interlayer insulating layers ITL4 remain.

Referring to FIG. 6O, conductive layers CD may fill the spaces between the fourth interlayer insulating layers ITL4. The conductive layers CD may be used as word lines or select lines of a memory block. Therefore, the conductive layers CD may be formed of a conductive material. For example, the conductive layers CD may be formed of a metal material, such as tungsten (W), molybdenum (Mo), cobalt (Co) or nickel (Ni), or a semiconductor material, such as silicon (Si) or poly-silicon (Poly-SI), but the present disclosure is not limited thereto.

Referring to FIG. 6P, an insulating layer IS may be formed along the side surface of the slit SLT, and a source contact SCT may be formed inside the slit SLT in which the insulating layer IS is formed. Since the insulating layer IS is formed along the side surface of the slit SLT, the third source layer 3SM that remains on the bottom of the slit SLT may be exposed through the slit SLT. Subsequently, when a conductive material for the source contact SCT fills the slit SLT, the third source layer 3Sm that is exposed through the bottom of the slit SLT may be in contact with the source contact SCT. Therefore, when a source voltage is applied to the source contact SCT, the source voltage may be transferred to the channel layer CH through the source structure SL and the compensation plug CPLc. The compensation plug CPLc can reduce a resistance between the source line SL and the cell plug CPL, and thus, the electrical characteristic of the memory device that uses the source line SL may be improved.

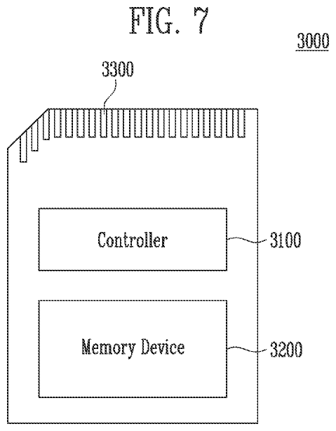

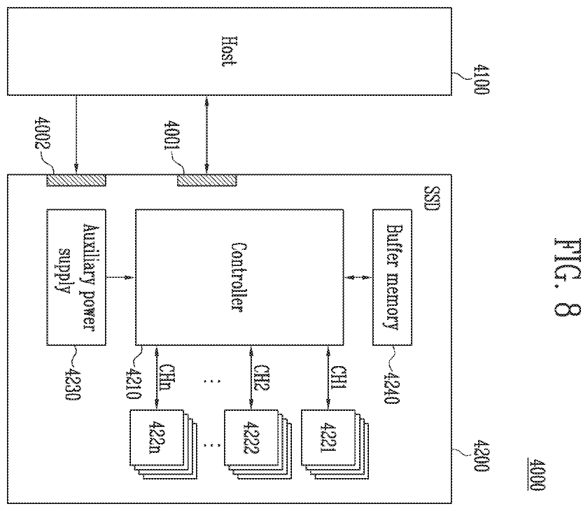

FIG. 7 is a diagram illustrating a memory card system to which the memory device of the present disclosure is applied.

Referring to FIG. 7, the memory card system 3000 includes a controller 3100, a memory device 3200, and a connector 3300.

The controller 3100 may be connected to the memory device 3200. The controller 3100 may access the memory device 3200. For example, the controller 3100 may control a program, read, or ease operation or may control a background operation of the memory device 3200. The controller 3100 may provide an interface between the memory device 3200 and a host. The controller 3100 may drive firmware for controlling the memory device 3200. For example, the controller 3100 may include components, such as a Random Access Memory (RAM), a processing unit, a host interface, a memory interface, and the error corrector.

The controller 3100 may communicate with an external device through the connector 3300. The controller 3100 may communicate with the external device (e.g., the host) according to a specific communication protocol. Exemplarily, the controller 3100 may communicate with the external device through at least one of various communication protocols, such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), firewire, a Universal Flash Storage (UFS), Wi-Fi, Bluetooth, and NVMe. Exemplarily, the connector 3300 may be defined by at least one of the above-described various communication protocols.

The memory device 3200 may include a plurality of memory cells and may be configured identically to the memory device 1100, shown in FIG. 1.

The controller 3100 and the memory device 3200 may be integrated into a single semiconductor device, constituting a memory card. For example, the controller 3100 and the memory device 3200 may constitute a memory card, such as a PC card (Personal Computer Memory Card International Association (PCMCIA)), a Compact Flash (CF) card, a Smart Media Card (SM and SMC), a memory stick, a Multi-Media Card (MMC, RS-MMC, MMCmicro and eMMC), an SD card (SD, miniSD, microSD and SDHC), and a Universal Flash Storage (UFS).

FIG. 8 is a diagram illustrating a Solid State Drive (SSD) system to which the memory device of the present disclosure is applied.

Referring to FIG. 8, the SSD system 4000 may include a host 4100 and an SSD 4200. The SSD 4200 may exchange a signal with the host 4100 through a signal connector 4001 and may receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to a signal received from the host 4100. Exemplarily, the signal may be a signal based on an interface between the host 4100 and the SSD 4200. For example, the signal may be a signal defined by at least one of interfaces such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), a firewire, a Universal Flash Storage (UFS), a WI-FI, a Bluetooth, and an NVMe.

The plurality of memory devices 4221 to 422n may include a plurality of memory cells configured to store data. Each of the plurality of memory devices 4221 to 422n may be configured identically to the memory device 1100 shown in FIG. 1. The plurality of memory devices 4221 to 422n may communicate with the controller 4210 through channels CH1 to CHn.

The auxiliary power supply 4230 may be connected to the host 4100 through the power connector 4002. The auxiliary power supply 4230 may receive power PWR that is input from the host 4100 and charge the power PWR. When the supply of power from the host 4100 is not smooth, the auxiliary power supply 4230 may provide power for the SSD 4200. Exemplarily, the auxiliary power supply 4230 may be located in the SSD 4200 or may be located at the outside of the SSD 4200. For example, the auxiliary power supply 4230 may be located on a main board and may provide auxiliary power to the SSD 4200.

The buffer memory 4240 may operate as a buffer memory of the SSD 4200. For example, the buffer memory 4240 may temporarily store data that is received from the host 4100 or data that is received from the plurality of memory devices 4221 to 422n, or temporarily store meta data (e.g., a mapping table) of the memory devices 4221 to 422n. The buffer memory 4240 may include volatile memories, such as a DRAM, an SDRAM, a DDR SDRAM, an LPDDR SDRAM, and a GRAM or nonvolatile memories such as a FRAM, a ReRAM, an STT-MRAM, and a PRAM.

In accordance with the present disclosure, a physical defect of a source line exposed through a landing hole in an etching process for forming the landing hole can be prevented and a resistance between the source line and a plug can be reduced.

While the present disclosure has been shown and described with reference to certain exemplary embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described exemplary embodiments but should be determined by not only the appended claims but also the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made based on the technological scope of the present disclosure.

Meanwhile, the exemplary embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made based on the technological scope of the present disclosure in addition to the embodiments disclosed herein.

What is claimed is:

1. A memory device comprising:
a source line;
a stack structure formed on the source line;
a cell plug penetrating the stack structure and contacting the source line;
a slit separating the stack structure;
a source contact formed in the slit, the source contact in contact with the source line; and
a compensation plug formed below the cell plug in the source line, wherein the compensation plug contains an impurity that has a higher concentration than an impurity that is contained in the source line.

2. The memory device of claim 1, wherein a top surface of the compensation plug is coupled to a bottom surface of the cell plug.

3. The memory device of claim 1, wherein the impurity is a phosphorous or boron ion.

4. The memory device of claim 1, wherein the cell plug is formed inside a plug hole that penetrates the stack structure and a landing hole that penetrates a portion of the source line.

5. The memory device of claim 4, wherein the cell plug includes:
a core pillar formed inside the plug hole and the landing hole;
a channel layer surrounding the periphery of the core pillar; and
memory layers surrounding the periphery of the channel layer.

6. The memory device of claim 5, wherein the memory layers are separated in a region in which the source line and the cell plug overlap with each other.

7. The memory device of claim 6, wherein the compensation plug is in contact with a memory layer, among the separated and isolated memory layers, located at a relatively lower portion.

8. The memory device of claim 5, wherein the core pillar and the channel layer extend from an uppermost end to a lowermost end of the cell plug.

9. The memory device of claim 1, wherein the source line, which contains the impurity, is formed of poly-silicon.

10. The memory device of claim 1, wherein the stack structure includes conductive layers and interlayer insulating layers, which are alternately stacked.

11. A method of manufacturing a memory device, the method comprising:
stacking a first source layer, a first sacrificial layer, and a second source layer on a lower structure;
forming a landing hole that exposes a portion of the first source layer by etching portions of the second source layer, the first sacrificial layer, and the first source layer;
forming a compensation plug on the bottom of the landing hole, wherein the compensation plug contains an impurity that has a higher concentration than an impurity that is contained in the first and second source layers;
filling the landing hole in which the compensation plug is formed with a second sacrificial layer;
forming third sacrificial layers and interlayer insulating layers, which are alternately stacked, on the entire structure including the second sacrificial layer;
forming a plug hole that exposes the second sacrificial layer by etching portions of the third sacrificial layers and the interlayer insulating layers;
exposing the compensation plug by removing the second sacrificial layer that is exposed through the plug hole; and
forming a cell plug on the top of the compensation plug that is exposed through the plug hole and the landing hole.

12. The method of claim 11, wherein the forming of the compensation plug includes:
filling the landing hole with poly-silicon for the compensation plug; and
allowing the compensation plug to remain on the bottom of the landing hole by removing a portion of the poly-silicon.

13. The method of claim 11, wherein the impurity is a phosphorous or boron ion.

14. The method of claim 11, wherein the concentration of the impurity that is contained in the first and second source layers is lower than a reference concentration, and
wherein the concentration of the impurity that is contained in the compensation plug is higher than the reference concentration.

15. The method of claim 11, wherein the first and second source layers are formed of poly-silicon.

16. The method of claim 11, wherein the forming of the cell plug includes:
forming a memory layer along inner surfaces of the plug hole and the landing hole in which the compensation plug is exposed;
forming a channel layer along an inner surface of the memory layer; and
filling a region that is surrounded by the channel layer with a core pillar.

17. The method of claim 16, wherein the forming of the memory layer includes:
forming a blocking layer along the inner surfaces of the plug hole and the landing hole in which the compensation plug is exposed;
forming a charge trap layer along an inner surface of the blocking layer; and
forming a tunnel insulating layer along an inner surface of the charge trap layer.

18. The method of claim 16, further comprising, after forming the cell plug:
forming a slit that exposes the first sacrificial layer by etching portions of the third sacrificial layers, the interlayer insulating layers, and the second source layer;
forming a recess between the first and second source layers by removing the first sacrificial layer that is exposed through the slit;
exposing a portion of the channel layer by removing a portion of the memory layer that is exposed through the recess;
filling the recess through which the portion of the channel layer is exposed with a third source layer;
removing the third sacrificial layers that is exposed through a side surface of the slit;
forming conductive layers in a region in which the third sacrificial layers are removed;
forming an insulating layer along an inner side surface of the slit; and
filling the slit in which the insulating layer is formed with a source contact.

19. The method of claim 18, wherein the third source layer is formed of a material containing the impurity that has a higher concentration than the impurity that is contained in the first or second source layer.
